(19) United States
(12) Patent Application Publication
(10) Pub. No.: US 2013/0068282 A1
(43) Pub. Date: Mar. 21, 2013

(54) SOLAR TRACKING WITH HEAT REJECTION

(71) Applicant: Karl S. Weibezahn, Corvallis, OR (US)

(72) Inventor: Karl S. Weibezahn, Corvallis, OR (US)

(21) Appl. No.: 13/236,933

(22) Filed: Sep. 20, 2011

(51) Int. Cl. H01L 31/052; F24J 2/30

(52) U.S. Cl. 136/246; 126/643

(57) ABSTRACT

Apparatus and methods related to solar energy are provided. A modular solar panel includes heat pipes to transfer heat away from photovoltaic cells. The solar panel is supported on a tracking mechanism and the heat pipes are coupled in thermal communication with heat exchangers. The solar panel is positioned by the tracking mechanism to follow the sun across the sky. Heat is transferred from the photovoltaic cells to the heat pipes and in turn to the heat exchangers, and is ultimately rejected from the system.

### STATEMENT OF GOVERNMENT INTEREST

The invention that is the subject of this patent application was made with Government support under Subcontract No. CW135971, under Prime Contract No. HR0011-Q7-9-0005, through the Defense Advanced Research Projects Agency (DARPA). The Government has certain rights in this invention.

### BACKGROUND

Concentrating solar energy systems use various optical elements such as lenses or reflectors to concentrate photonic energy (i.e., sunlight) onto photovoltaic cells. Fewer or smaller photovoltaic cells can be used relative to non-concentrating systems, resulting in reduced manufacturing costs. Additionally, state-of-the-art photovoltaic cells can be applied within systems that are cost-effective.

However, concentrated solar energy results in significant heating of the photovoltaic cells. This heat must be rejected in the interest of cell operating efficiency. The present teachings address the foregoing concerns and other concerns.

### BRIEF DESCRIPTION OF THE DRAWINGS

The present embodiments will now be described, by way of example, with reference to the accompanying drawings, in which:

FIG. 1 depicts a solar energy system according to one example;

FIG. 2 depicts a solar energy system according to another example;

FIG. 3 depicts an isometric-like view of an array of heat exchangers on a supporting framework according to another example;

FIG. 4 depicts a block diagram of a solar energy system according to an example;

FIG. 5 depicts a flow diagram of a method according to another example.

### DETAILED DESCRIPTION

### Introduction

Apparatus, systems and methods related to solar energy are provided. A modular solar panel includes photovoltaic cells and heat pipes configured to transfer heat away from the photovoltaic cells. The solar panel is supported on a tracking mechanism or tracker, and the heat pipes are engaged with corresponding heat exchangers. The solar panel is thereafter positioned by the tracking mechanism so as to follow the apparent motion of the sun across the sky.

Electrical energy generated by the photovoltaic cells is provided to an electrical load or loads. Heat is transferred from the photovoltaic cells to the heat pipes and in turn to the heat exchangers, and is ultimately rejected from the system overall. Solar panels having heat pipes are modular in nature, and heat exchangers and trackers can accommodate advancements in photovoltaic cell or other related technology.

In one example, a device includes a support structure configured to be angularly repositioned with respect to the sun. The device also includes one or more heat exchangers supported by the support structure. Each heat exchanger is configured to be joined in thermal communication with at least one heat pipe of a solar panel.

In another example, a solar energy system includes a solar panel having a plurality of photovoltaic cells and a plurality of heat pipes to transfer heat away from the photovoltaic cells. The solar energy system also includes a tracking mechanism to angularly reposition the solar panel in accordance with an apparent motion of the sun across the sky. The solar energy system further includes a plurality of heat exchangers borne by the tracking mechanism. Each heat exchanger is in thermal communication with one or more of the heat pipes, and is configured to reject heat received from the one or more heat pipes.

### First Illustrative System

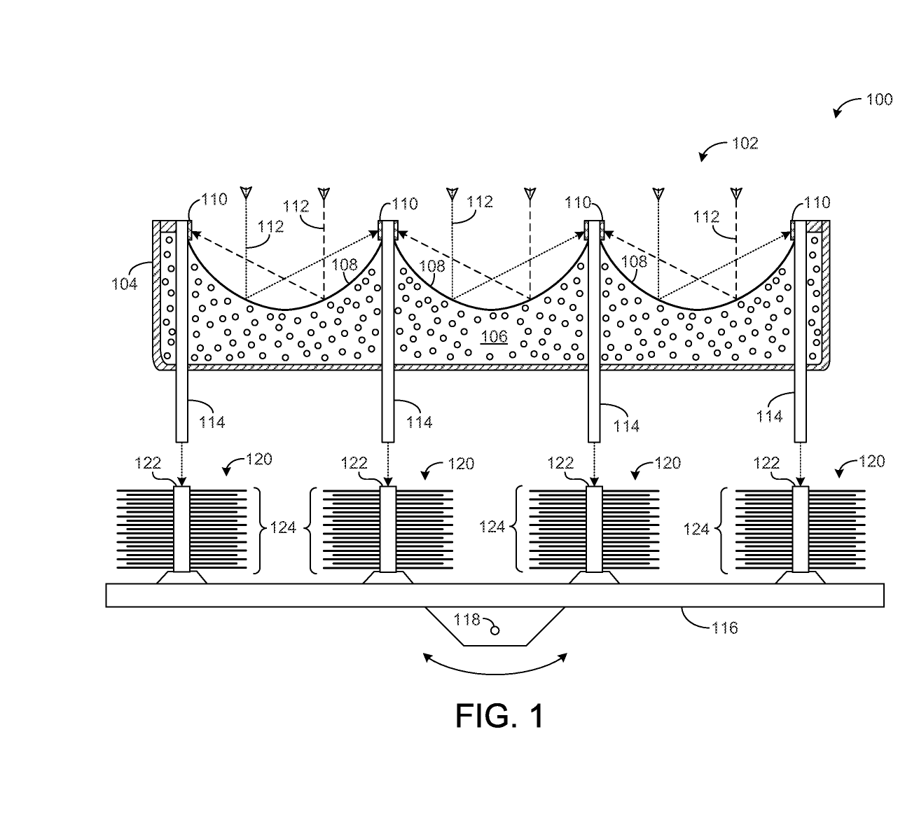

Reference is now made to FIG. 1, which depicts a system 100. The system 100 is illustrative and non-limiting in nature. Thus, other devices, apparatus and systems are contemplated by the present teachings. The system 100 is also referred to as a solar energy system 100 or photonic energy system 100 for purposes herein.

The system 100 includes a solar panel (panel) 102. The panel 102 includes a housing 104 and a solid foam material 106 which cooperate to support a plurality of light (photonic energy) concentrators 108. The panel 102 also includes a plurality of photovoltaic cells 110 configured to generate or derive electrical energy by direct conversion of incident photonic energy.

Each light concentrator 108 is defined by a surface curvature and a reflective or dichroic surface treatment thereon so as to concentrate photonic energy 112, such as sunlight, onto a photovoltaic cell or cells 110. The photovoltaic cells 110 can be electrically coupled to an electrical load or loads as further described below.

The panel 102 also includes a plurality of heat pipes 114. Each heat pipe 114 is in thermal communication with one or more of the photovoltaic cells 110. That is, each heat pipe 114 is configured to transfer heat energy away from a respective number of photovoltaic cells 110 such that the photovoltaic cells 110 are kept within suitable operating temperature limits. The heat pipes 114 can be formed from metal or another material and can include, without limitation, internal fins, wicking or capillary material, a fluid fill such as water, alcohol, or another suitable fluid, and so on.

Typically, but not necessarily, heat transfer to a heat pipe 114 results in a change-of-phase (liquid to vapor) of a fluid inside, which flows away from the source of heat at one end so as to reject the heat at an opposite end. The cooled fluid then reverses the change-of-phase (vapor to liquid) and flows back to the heated end of the heat pipe 114 such that continuous heat transfer is performed. One having ordinary skill in the mechanical, thermodynamic or related arts is familiar with heat transfer by way of heat pipes, and further elaboration as to particular operation or constituency is not germane to the present teachings.

The system 100 also includes a tracking mechanism or tracker 116. The tracker 116 is configured to pivot about an axis 118 so that angular displacement or positioning of the tracker 116 can be performed. Such positioning is typically performed by way of automated motor-driven control so as to track an apparent motion of the sun across the sky during daylight hours. In another example, the tracking mechanism can pivot independently about two orthogonal axis (i.e., altitude and azimuth). Other configurations can also be used.

The system 100 further includes a plurality of heat exchangers 120. Each heat exchanger 120 is supported by or joined to the tracker 116 and is configured to be coupled in thermal communication with a respective one of the heat pipes 114. In particular, each heat exchanger 120 is formed from metal such as, without limitation, aluminum, copper and so on, and is characterized by a tube or conduit 122 configured to slidingly receive a heat pipe 114 there in. Thus, each heat exchanger 120 is in thermally conductive contact with a heat pipe 114 when the solar panel 102 is joined (or mated) to the tracker 116. Each heat exchanger 120 also includes a plurality of heat dissipation fins (fins) 124 configured to reject heat to the ambient environment by way of convection and/or radiation.

Typical, illustrative operations of the system 100 are as follows: the solar panel 102 is supported on the tracker 116 such that the heat pipes 114 are slidingly received within respective ones of the conduits 122. The heat pipes 114 are thus in thermally communicative contact with respective heat exchangers 120. Supports, connectors, threaded fasteners or other mechanical constituents that are not germane to the present teachings can be used to mechanically couple the solar panel 102 to the tracker 116.

The tracker 116 is then angularly positioned about the axis 118 in a continuous or incremental manner so as to keep the solar panel 102 trained on the sun (or another source of photonic energy). The photovoltaic cells 110 generate electrical energy by direct conversion and that electrical energy is provided to a load (described hereinafter). The concentrated photonic energy 112 results in significant heating of the photovoltaic cells 110, which is transferred to the heat pipes 114.

The heat pipes 114 convey or transfer heat energy away from the photovoltaic cells 110 to respective ones of the heat exchangers 120. In turn, the heat exchangers 120 reject the heat to the ambient environment by way of the heat dissipation fins 124. The system 100 can thus operate in an ongoing manner so as to generate electrical energy by way of the photovoltaic cells 110, while rejecting heat by way of the heat pipes 114 and heat exchangers 120.

### Second Illustrative System

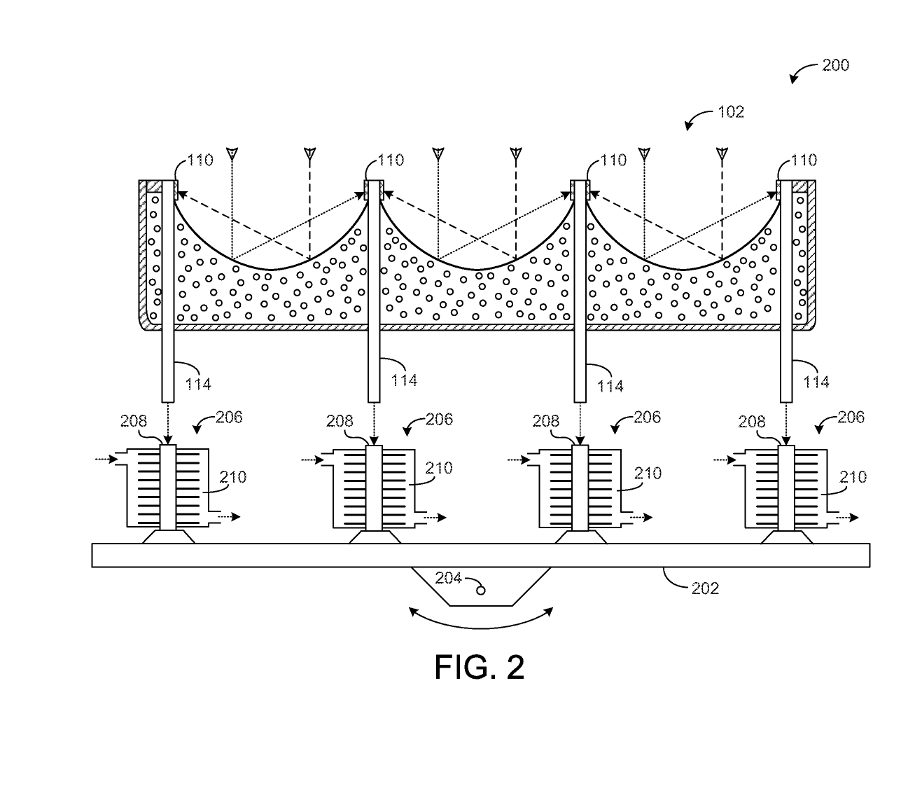

Reference is now directed to FIG. 2, which depicts a system 200. The system 200 is illustrative and non-limiting in nature. Thus, other devices, apparatus and systems are contemplated by the present teachings. The system 200 is also referred to as a solar energy system 200 or photonic energy system 200 for purposes herein.

The system 200 includes the solar panel (panel) 102 as described above. The panel 102 thus includes heat pipes 114 in thermal communication with respective numbers of photovoltaic cells 110, and so on.

The system 200 also includes a tracking mechanism or tracker 202. The tracker 202 is configured to pivot about an axis 204 so that angular displacement or positioning of the tracker 202 can be performed in accordance with single-axis concentration of solar energy. Such positioning is typically performed by way of automated motor-driven control in accordance with the motion of the sun across the sky. In another example, the tracker is configured to pivot about two respective axis in accordance with two-axis concentration of solar energy.

The system 200 further includes a plurality of heat exchangers 206. Each heat exchanger 206 is supported by (or joined to) the tracker 202 and is configured to be thermally coupled to a respective one of the heat pipes 114. Specifically, each heat exchanger 206 is formed from metal or another suitable material and is characterized by a tube or conduit 208 configured to slidingly receive a heat pipe 114 there in. Thus, each heat exchanger 206 is in thermally conductive contact with a heat pipe 114 when the solar panel 102 is joined (or mated) to the tracker 202.

Each heat exchanger 206 is further characterized by an internal cavity 210 configured such that a fluid coolant can flow there through. Such a flow of fluid coolant can be defined by, without limitation, water, alcohol, glycol or another suitable media. Heat is rejected from each heat exchanger 206 by way of such a fluid coolant flow.

Typical, illustrative operations of the system 200 are as follows: the solar panel 102 is joined to the tracker 202 by sliding reception of the heat pipes 114 within respective ones of the conduits 208. Thermal communication between the heat pipes 114 and respective heat exchangers 206 is therefore established. The solar panel 102 is mechanically supported on the tracker 202 by way of threaded fasteners, structural framework and so on. A flow of fluid coolant is then provided through the heat exchanger 206 by way of another entity or source described below.

The tracker 202 is then angularly positioned about the axis 204 so as to keep the solar panel 102 trained on the sun (or another source of photonic energy). The photovoltaic cells 110 generate electrical energy, which is provided to an electrical load or loads (described hereinafter), Concentrated photonic energy results in significant heating of the photovoltaic cells 110, which is transferred to the heat pipes 114.

The heat pipes 114 convey or transfer heat energy away from the photovoltaic cells 110 to respective ones of the heat exchangers 206. In turn, each heat exchanger 206 rejects heat to a flow of fluid coolant through the corresponding internal cavity 210. The system 200 can operate in continuous or “steady-state” manner, generating electrical energy and rejecting heat.

### Illustrative Heat Exchanger Array

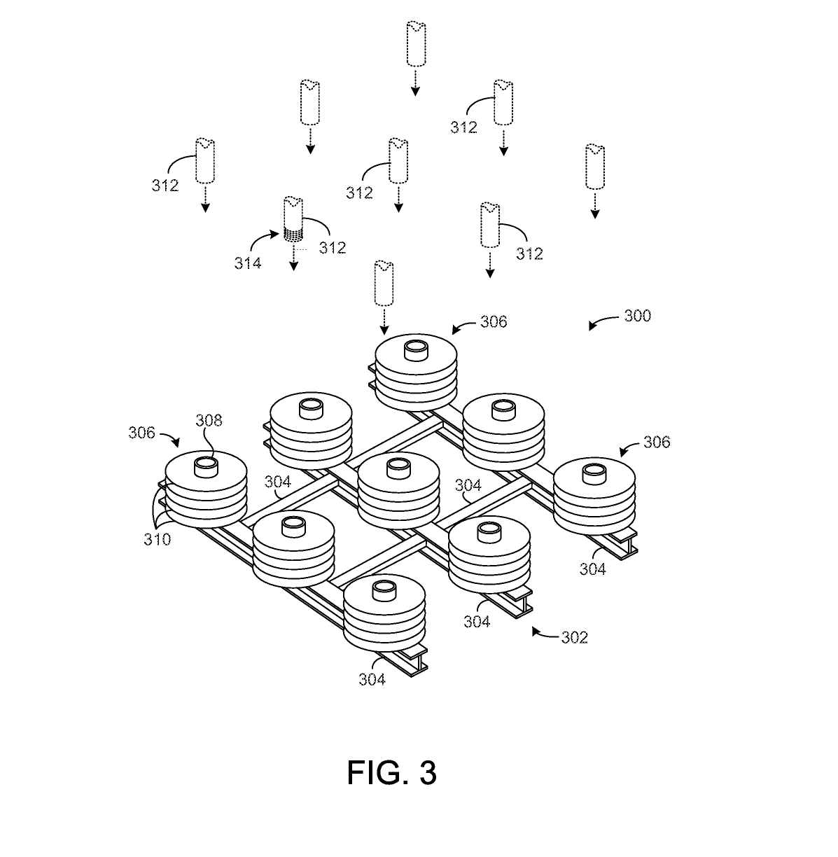

Attention is now turned to FIG. 3, which depicts a heat exchanger array (array) 300. The array 300 is illustrative and non-limiting with respect to the present teachings. Other arrays, structures, constituencies or configurations can also be used.

The array 300 includes a support structure or framework 302 comprised of respective beam-like members 304. The framework 302 is configured to be angularly positioned so as to follow (track) an apparent motion of the sun across the sky during normal operation. The framework 302 is characterized by an open or “skeletal” form factor by virtue of the beam-like members 304. Other form factors, structural elements (e.g., rods, bars, threaded fasteners and so on) can also be used. In another example, a support structure is defined by a planar surface or platen.

The array 300 also includes a plurality of heat exchangers 306 formed from metal or another suitable thermally-conductive material. A total of nine heat exchangers 306 are included, arranged as a 3-by-3 array and supported on the framework 302. The present teachings contemplate other arrays having any suitable respective number of heat exchangers, arranged in any suitable pattern.

Each of the heat exchangers 306 includes a central conduit or tube 308 and a plurality of heat dissipation fins 310 supported in spaced distribution along the tube 308. Each of the tubes 308 is configured to slidingly receive a respective heat pipe 312 of a solar panel (e.g., 102). Thermal communication between a heat exchanger 306 and a corresponding heat pipe 312 is provided by such a mated arrangement. Thermal paste 314, as is familiar to one having ordinary skill in the electrical or other arts, can be used to provide improved thermal communication from each heat pipe 312 to the corresponding heat exchanger 306.

Each of the heat exchangers 306 can be supported so as to be independently repositionable (tilted or translated) with respect to the framework 302, at least a relatively minor degree. Such repositionability allows each heat exchanger 306 to adjust as needed in order to receive a corresponding one of the heat pipes 312. Such repositionability can be provided by way of adjustable threaded fasteners, pliable mounting compounds such as rubber or silicone, and the like.

### Illustrative Block Diagram of a System

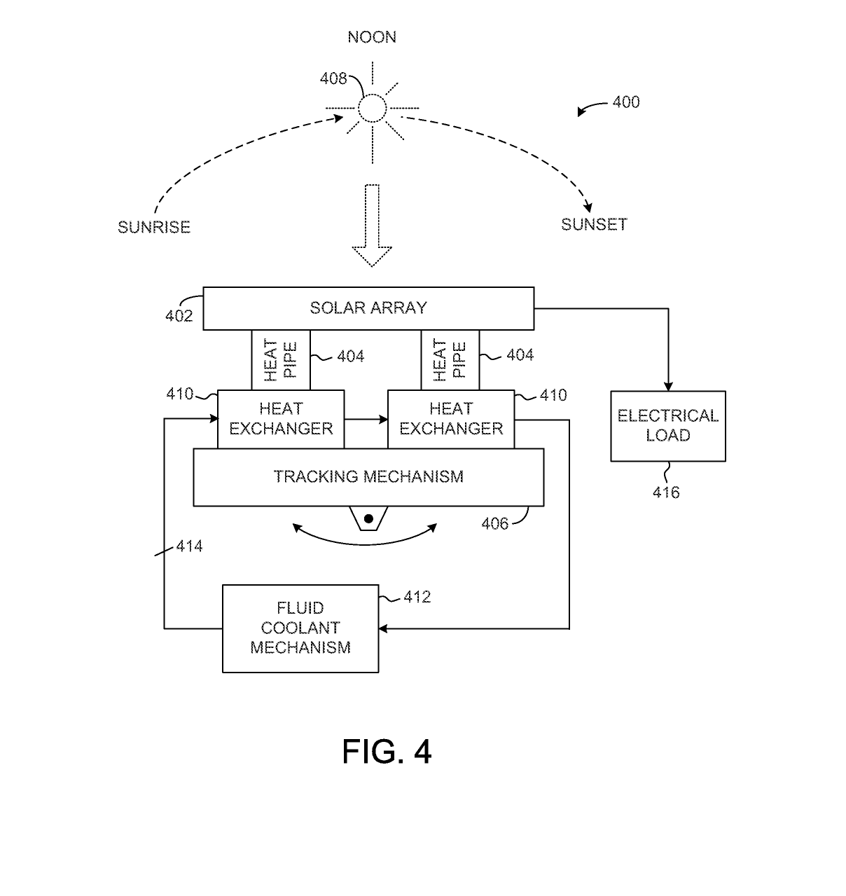

Attention is now directed to FIG. 4, which depicts a block diagram of a solar energy system (system) 400. The system 400 is illustrative and non-limiting in nature, and is directed to clarity of the present teachings. Other systems, devices and apparatus, and their respective operating characteristics, are also contemplated.

The system 400 includes a solar panel 402. The solar panel 402 has a generally panel or platen-like form factor, being self-contained and modular in the sense that it can be readily engaged and disengaged from a supportive tracking mechanism. The solar panel 402, considered as a discrete entity, includes a plurality of photovoltaic cells (e.g., 110) that provide electrical energy during normal typical operation. Heat incident to operation is transferred or by way of respective heat pipes 404 of the solar panel 402.

The system 400 also includes a tracking mechanism 406. The tracking mechanism 406 is configured to automatically position the solar panel 402 so as to track or follow an apparent motion of the sun 408 across the sky. The tracking mechanism 406 includes a plurality of heat exchangers 410 supported thereon. Each heat exchanger 410 is configured to be mated in thermal communication with a respective one of the heat pipes 404. Thermal energy is transferred (or rejected) from the solar panel 402 through the heat pipes 404 to the heat exchangers 410 during normal operation.

The system 400 also includes a fluid coolant mechanism 412 configured to drive a flow of fluid coolant 414 through the respective heat exchangers 410. Such coolant can be any suitable media such as water, alcohol, and so on. The fluid coolant mechanism 412 is further configured to reject heat to the ambient environment by way of convection, radiation or the like. In this way, heat is removed from the solar panel 402 and ultimately rejected from the system 400. The particular mechanism used to reject heat from the fluid coolant mechanism 412 can be any that is familiar to the one of ordinary skill in the relevant art and is not germane to the present teachings.

The system 400 includes an electrical load 416 coupled to receive electrical energy from the solar panel 402. The electrical load 416 can be defined by any suitable device or sub-system such as, for non-limiting example, a power supply, a storage battery, a power inverter, a radio transceiver, a global positioning system (GPS) receiver, a computer, and so on. Other electrical loads 416 can also be used.

During normal typical operation, the sun 408 provides photonic energy that is incident to the solar panel 402. Photovoltaic cells within the solar panel 402 provide electrical energy to the electrical load 416. Heat is transferred from the photovoltaic cells to the heat pipes 404.

Heat is further transferred from the heat pipes 404 to the heat exchangers 410 and then to the flow of fluid coolant 414. Heat is then rejected from the system 400 altogether by way of the fluid coolant mechanism 412.

The tracking mechanism 406 continuously or incrementally repositions the solar panel 402 so as to maintain (about) optimum orientation with respect to the sun 408. The system 400 can thus operate in a continuous manner during daylight hours, resetting itself for operation during another daily cycle.

### Illustrative Method

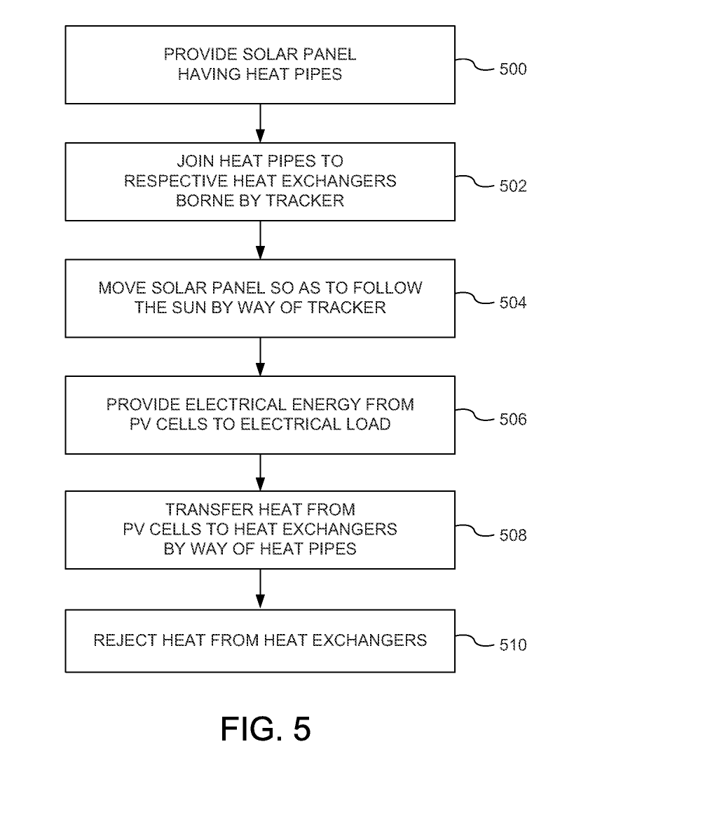

Attention is now directed to FIG. 5, which depicts a flow diagram of a method according to another example of the present teachings. The method of FIG. 5 includes particular steps and proceeds in a particular order of execution. However, it is to be understood that other respective methods including other steps, omitting one or more of the depicted steps, or proceeding in other orders of execution can also be used. Thus, the method of FIG. 5 is illustrative and non-limiting with respect to the present teachings. Reference is also made to FIGS. 1 and 4 in the interest of understanding the method of FIG. 5.

At 500, a solar panel is provided that includes heat pipes. For purposes of a present example, a solar panel 102 is provided that includes heat pipes 114.

At 502, heat pipes are joined to respective heat exchangers borne by a tracker. For purposes of the present example, the heat pipes 114 are slidingly received within respective ones of tubes (or conduits) 122 of heat exchangers 120. Thermally conductive contact between the heat pipes 114 and the heat exchangers 120 is thus established. Other mechanical elements are used to supportively join the solar panel 102 to the tracker 116.

At 504, the solar panel is moved to follow the sun by way of the tracker. For purposes of the present example, the tracker 116 pivots about an axis 118 so as to keep the solar panel 102 trained on the sun (e.g., 408).

At 506, electrical energy is provided from photovoltaic (PV) cells of the solar panel to an electrical load. In the present example, the solar panel 102 includes PV cells 110 that generate electrical energy from the sunlight 112 concentrated there on. The electrical energy is provided to an electrical load (e.g., 416) external to the solar panel 102.

At 508, heat is transferred from the photovoltaic cells to the heat exchangers by way of the heat pipes. In the present example, heat (thermal energy) is transferred from the PV cells 110 to corresponding heat exchangers 120 by way of heat pipes 114.

At 510, heat is rejected from the heat exchangers. For purposes of the present example, heat is ultimately rejected to the ambient environment by way of heat dissipation fins 124 born on the outside surface of the heat exchangers 120. Heat is thus rejected from the PV cells 110 to the environment providing for sustained operation under concentrated solar energy exposure.

The method above is described in the context of discrete steps occurring in a sequential order, in the interest of clarity. It is to be understood that various processes or operations of the present teachings can occur contemporaneously or essentially so. Thus, for non-limiting example, electrical energy can be provided from PV cells to an electrical load, while thermal energy is contemporaneously rejected from the corresponding solar panel.

Additionally, the heat exchangers described in the method above dissipate heat to the environment by way of external fins. In another example, heat is rejected from a solar energy system by way of circulated fluid coolant flow (e.g., 414) through respective heat exchangers (FIG. 4). Other suitable heat rejection schema can also be used. In yet another example, the solar panel includes a transparent cover to protect the photovoltaic cells (e.g., 110) within from environmental hazards such as dust, hail, rain, ice, and so on.

In general and without limitation, the present teachings contemplate various devices and systems and methods of their use. A system includes a solar panel having integrated heat pipes for removal of heat from photovoltaic cells during normal operation. Such a solar panel can be considered as a modular or unitary entity, lending itself to convenient storage, transportation, or setup and is unencumbered by fluidic tubing, large and/or heavy heat dissipation fins, and so on.

The solar panel is mechanically joined to a tracking mechanism (or tracker) and thermal communication is established between the heat pipes and corresponding heat exchangers. The heat exchangers are supported by and considered a part of the tracking mechanism. Additionally, the heat exchangers can be independently repositioned with respect to the tracking mechanism so as to accommodate sliding reception of the heat pipes in those embodiments. Other thermal or mechanical mating of the heat pipes with the heat exchangers can also be used.

The tracking mechanism is then driven to continuously or incrementally reposition the solar panel so as to follow the apparent motion of the sun across the sky during daylight hours. Such tracking can be performed in accordance with single-axis or two-axis positioning schema, depending upon the solar energy concentrator configuration of the solar panel. The solar panel is thus optimally oriented or nearly so in order to derive maximum electrical yield from the photovoltaic cells.

The heat is transferred from the photovoltaic cells to the heat pipes and from there to the heat exchangers during normal operation. The heat exchangers then dissipate the heat to the ambient environment directly, or transfer the heat to a flow of fluid coolant. Ultimately, heat is rejected from a solar panel without need to include a complete heat rejection system within the solar panel itself. Modular system design, capable of accommodating advancements in photovoltaic cells, heat pipes or other constituency is therefore contemplated by the present teachings.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

1. A device, comprising:
a support structure configured to be angularly repositioned with respect to the sun; and
one or more heat exchangers supported by the support structure, each heat exchanger configured to be joined in thermal communication with at least one heat pipe of a solar panel, at least one of the heat exchangers characterized by an internal cavity and configured to reject heat by way of a fluid flow through the internal cavity.

2. The device according to claim 1, at least one of the heat exchangers including a conduit configured to slidingly receive one or more heat pipes of a solar panel.

3-4. (canceled)

5. The device according to claim 1, the at least one heat exchanger configured to be fluidly coupled to a source of fluid coolant.

6. The device according to claim 1, at least one of the heat exchangers being repositionable with respect to the support structure.

7. The device according to claim 1 further comprising a thermal paste configured to conduct thermal energy from at least one heat pipe to at least one of the heat exchangers.

8. A solar energy system, comprising:
a solar panel having a plurality of photovoltaic cells and a plurality of heat pipes to transfer heat away from the photovoltaic cells;
a tracking mechanism to angularly reposition the solar panel in accordance with an apparent motion of the sun across the sky; and
a plurality of heat exchangers borne by the tracking mechanism, each heat exchanger in thermal communication with one or more of the heat pipes, each heat exchanger configured to reject heat received from the one or more heat pipes, at least one of the heat exchangers including an internal cavity to reject heat by way of a fluid coolant flowing there through.

9. (canceled)

10. The solar energy system according to claim 8, at least one of the heat exchangers being repositionable with respect to the tracking mechanism so as to accommodate thermal communication with one or more of the heat pipes.

11. (canceled)

12. The solar energy system according to claim 8 further comprising a mechanism to drive a flow of the fluid coolant through the at least one heat exchanger.

13. The solar energy system according to claim 8 further comprising an electrical bad coupled to receive electrical energy from the photovoltaic cells.
